(19) United States
(12) Patent Application Publication
(10) Pub. No.: US 2011/0136304 A1
(43) Pub. Date: Jun. 9, 2011

(54) Techniques to Enhance Selectivity of Electrical Breakdown of Carbon Nanotubes

(75) Inventors: Eric W. Wong, Los Angeles, CA (US); Brian D. Hunt, La Crescenta, CA (US); Rajay Kumar, Huntington Beach, CA (US); Chao Li, Arcadia, CA (US)

(73) Assignee: ETAMOTA CORPORATION, Pasadena, CA (US)

(21) Appl. No.: 12/814,254

(22) Filed: Jun. 11, 2010

Related U.S. Application Data
(60) Provisional application No. 61/186,368, filed on Jun. 11, 2009.

(51) Int. Cl. H01L 21/338; B82Y 40/00

(52) U.S. Cl. 438/167; 977/742; 257/E21.45

(57) ABSTRACT

Techniques are used to fabricate carbon nanotube devices. These techniques improve the selective removal of undesirable nanotubes such as metallic carbon nanotubes while leaving desirable nanotubes such as semiconducting carbon nanotubes. In a first technique, slot patterning is used to slice or break carbon nanotubes have a greater length than desired. By altering the width and spacing of the slotting, nanotubes have a certain length or greater can be removed. Once the lengths of nanotubes are confined to a certain or expected range, the electrical breakdown approach of removing nanotubes is more effective. In a second technique, a Schottky barrier is created at one electrode (e.g., drain or source). This Schottky barrier helps prevent the inadvertent removal the desirable nanotubes when using the electrical breakdown approach. The first and second techniques can be used individually or in combination with each other.

### CROSS-REFERENCE TO RELATED APPLICATIONS

This application claims the benefit of U.S. provisional patent application 61/186,368 filed Jun. 11, 2009, which is incorporated by reference along with all other cited references in this application.

### BACKGROUND OF THE INVENTION

The present invention relates to semiconductor devices and their manufacture, and more specifically to fabricating carbon nanotube devices.

The age of information and electronic commerce has been made possible by the development of transistors and electronic circuits, and their miniaturization through integrated circuit technology. Integrated circuits are sometimes referred to as “chips.” Many numbers of transistors are used to build electronic circuits and integrated circuits. Modern microprocessor integrated circuits have over 50 million transistors and will have over 1 billion transistors in the future.

Some type of circuits include digital signal processors (DSPs), amplifiers, dynamic random access memories (DRAMs), static random access memories (SRAMs), erasable programmable read only memories (EPROMs), electrically erasable programmable read only memories (EEPROMs), Flash memories, microprocessors, application specific integrated circuits (ASICs), and programmable logic. Other circuits include amplifiers, operational amplifiers, transceivers, power amplifiers, analog switches and multiplexers, oscillators, clocks, filters, power supply and battery management, thermal management, voltage references, comparators, and sensors.

Electronic circuits have been widely adopted and are used in many products in the areas of computers and other programmed machines, consumer electronics, telecommunications and networking equipment, wireless networking and communications, industrial automation, and medical instruments, just to name a few. Electronic circuits and integrated circuits are the foundation of computers, the Internet, voice over IP (VoIP), video on demand (VOD), and on-line technologies including the World Wide Web (WWW).

There is a continuing demand for electronic products that are easier to use, more accessible to greater numbers of users, provide more features, and generally address the needs of consumers and customers. Integrated circuit technology continues to advance rapidly. With new advances in technology, more of these needs are addressed. Furthermore, new advances may also bring about fundamental changes in technology that profoundly impact and greatly enhance the products of the future.

The building blocks in electronics are electrical and electronic elements. These elements include transistors, diodes, resistors, and capacitors. There are many numbers of these elements on a single integrated circuit. Improvements in these elements and the development of new and improved elements will enhance the performance, functionality, and size of the integrated circuit.

An important building block in electronics is the transistor. In fact, the operation of almost every integrated circuit depends on transistors. Transistors are used in the implementation of many circuits. Improving the characteristics and techniques of making transistors will lead to major improvements in electronic and integrated circuit.

Presently silicon-based metal-oxide-semiconductor field-effect transistors (MOSFETs) are the workhorses of electronic systems and power electronics systems. However, demand for increasing performance requirements is pushing the boundaries of silicon material. It is desirable to have transistors with improved characteristics, especially transistors having higher current density, higher thermal conductivity, and higher switching frequency.

Carbon nanotube (CNT) field-effect transistors (FETs) show great promise for high power and high frequency electronics applications. However, carbon nanotubes as grown typically contain a mix of semiconducting and metallic tubes. For proper transistor operation, the metallic nanotubes must be selectively removed without damaging the semiconducting carbon nanotubes. This is difficult to do with conventional chemical techniques, because there is very little chemical difference between the two types of nanotubes.

Therefore, there is a need for a technique to selective remove the metallic carbon nanotubes while leaving the semiconducting carbon nanotubes.

### BRIEF SUMMARY OF THE INVENTION

Techniques are used to fabricate carbon nanotube devices. These techniques improve the selective removal of undesirable nanotubes such as metallic carbon nanotubes while leaving desirable nanotubes such as semiconducting carbon nanotubes.

In a first technique, slot patterning is used to slice or break carbon nanotubes that have a greater length than desired. By altering the width and spacing of the slotting, nanotubes that have a certain length or greater can be removed. Once the lengths of nanotubes are confined to a certain or expected range, the electrical breakdown approach of removing nanotubes is more effective.

In a second technique, a Schottky barrier is created at one electrode (e.g., drain or source). This Schottky barrier helps prevent the inadvertent removal of desirable nanotubes when using the electrical breakdown approach. The first and second techniques can be used individually or in combination with each other.

In an implementation, a method includes: providing a silicon substrate; forming on a surface of the substrate a mixture of semiconducting and metallic carbon nanotubes; on the mixture, patterning a first slot and second slot, each having a width W and a spacing S between the first and second slot, where W is less than S; etching the mixture in the slots; removing the patterning; forming drain and source electrodes contacting ends of the mixture; and biasing the drain and source electrode with voltage to remove the metallic carbon nanotubes.

The method may further include forming a Schottky barrier between an end of the mixture and the source electrode.

In another implementation, a method includes: providing a silicon substrate; forming on a surface of the substrate a mixture of semiconducting and metallic carbon nanotubes; on the mixture, patterning a first slot and second slot, each having a width W and a spacing S between the first and second slot, where W is less than S; forming drain and source electrodes contacting ends of the mixture, where between a first end of the mixture and the source electrode is a Schottky barrier contact; and biasing the drain and source electrode with voltage to remove the metallic carbon nanotubes.

The method may further includes before forming the Schottky barrier: etching the mixture in the slots; and removing the patterning. Also, between a second end of the mixture and the drain electrode is an ohmic contact.

In an implementation, a method includes: providing a substrate; forming on a surface of the substrate a mixture of semiconducting and metallic carbon nanotubes; forming a source electrode including a Schottky barrier contact that connects to first ends of the mixture; forming a drain electrode that electrically connects to second ends of the mixture; and biasing the drain and source electrode with a voltage to remove the metallic carbon nanotubes.

As a result of the biasing, greater numbers of metallic carbon nanotubes are removed from the mixture than semiconducting carbon nanotubes. The numbers of metallic carbon nanotubes removed relative to the semiconducting carbon nanotubes will depend on conditions (as discussed in more detail below) including voltage level, concentrations, and temperature.

For example, as a result of the biasing, at least twice as many metallic carbon nanotubes are removed than semiconducting carbon nanotubes. As a result of the biasing, at least five times more metallic carbon nanotubes are removed than semiconducting carbon nanotubes. As a result of the biasing, at least ten times more metallic carbon nanotubes are removed than semiconducting carbon nanotubes. As a result of the biasing, at least twenty times more metallic carbon nanotubes are removed than semiconducting carbon nanotubes. In other implementations, at 30, 50, 60, 75, 100, 150, 500, 1000, or 10,000 or times more metallic carbon nanotubes are removed than semiconducting carbon nanotubes.

Before forming the Schottky barrier, the method may further include: on the mixture, patterning a first slot and second slot, each having a width W and a spacing S between the first and second slot, wherein W is less than S; etching the mixture in the slots; and removing the slot patterning. The patterning may be done using a photoresist. The areas without photoresist are slots where features in the slots (e.g., nanotubes) can be etched.

In a specific implementation, a first carbon nanotube of the mixture crosses and couples to at least a second carbon nanotube and a third carbon nanotube. On the mixture, a first slot and second slot are patterned, each slot having a width W and a spacing S between the first and second slot, wherein W is less than S. The mixture in the slots is etched, where the first carbon nanotube is sliced below the first slot and the second slot. This breaks the first carbon nanotubes into at least three portions.

In a specific implementation, the source electrode includes a rectangular structure (e.g., polyon) having a width SW and length SL. The drain electrode includes a rectangular structure having a width DW and length DL. Length SL is greater than width SW. Length DL is greater than width DW. The source is separated from the drain a space having a width D.

A first carbon nanotube of the mixture extends from the first electrode to the second electrode and has a length L1 greater than D. A second carbon nanotube of the mixture extends from the first electrode to the second electrode and has a length L2 greater than L1, wherein an angle A1 between the first carbon nanotube and the first electrode is different from an angle A2 between the second carbon nanotube and the first electrode.

Before forming the mixture, on the substrate a thermal gate oxide is formed having a thickness from about 2 nanometers to about 500 nanometers. The source electrode and drain electrode include at least one of metal, polysilicon, aluminum, copper, titanium, or tungsten.

Before forming the mixture, a catalyst is formed or deposited on the substrate comprising at least one of palladium, iron, nickel, or cobalt. The catalyst assists the formation of the nanotubes. The nanotubes form off the deposited catalyst. The nanotubes touch the catalyst material. After the nanotubes are formed, the catalyst material can be removed.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIG. 1 shows a side view of a structure with a carbon nanotube extending between a source electrode and drain electrode.

FIG. 2 shows a top view of the structure with a number of carbon nanotubes.

FIG. 3 shows a top view of the structure with slots used to break the carbon nanotubes.

FIGS. 4A-4C show curves for a typical breakdown for a device without periodic slicing.

FIGS. 5A-5C show curves for a typical breakdown for a device with periodic slicing.

FIGS. 6A-6B show side and top views of a substrate after the carbon nanotubes, a mixture of s-CNTs and m-CNTs, are formed.

FIGS. 7A-7B show side and top views of a pattern of slots (open regions) without photoresist and other regions covered with photoresist.

FIGS. 8A-8B show side and top view of etching of the slotted regions, so the nanotubes in slots are sliced.

FIG. 9 shows a top view of the structure when the resist is removed and the broken nanotubes remain.

FIG. 10 shows the structure after drain and source electrodes are formed.

FIG. 11 shows the structure after m-CNTs are selectively removed using an electrical breakdown technique.

FIG. 12 shows the structure after a top gate with a thin barrier is formed.

FIG. 13 shows a side view of a structure with a carbon nanotube extending between a source electrode and drain electrode, where there is a Schottky contact between the source electrode an end of the carbon nanotube.

FIGS. 14A-14D show a comparison of the results of using a Schottky barrier technique versus using only ohmic contacts.

FIG. 15 shows a two nanotubes which do not cross, where one of the ends is connected to a small Schottky barrier contact.

FIG. 16 shows a two nanotubes which cross, resulting in a large leakage current between the ohmic contacts.

FIG. 17 shows a two nanotubes which do not cross, where one of the ends is connected to a large Schottky barrier contact.

FIG. 18 shows a two nanotubes which cross, where one of the ends is connected to a large Schottky barrier contact.

FIGS. 19A-19B show diagrams for a device where the source contact is characterized to be a Schottky contact.

FIGS. 20A-20B show the Schottky contact of FIG. 19B when the junction is reverse biased (FIG. 20A) and forward biased (FIG. 20B).

### DETAILED DESCRIPTION OF THE INVENTION

Carbon nanotubes are known to typically grow in a mixture of semiconducting and metallic species. The invention relates to the fabrication of nanotube (CNT) devices such as carbon nanotube transistors that require purely semiconducting nanotubes (s-CNT), or that involve substantially more s-CNTs than metallic nanotubes (m-CNTs).

An aspect of the invention is a method to vastly improve the selectivity of a process for electrically breaking down m-CNTs to leave a device having substantially more or purely s-CNTs. It is desirable to have a highly selective breakdown process where selectivity refers to breakdown of m-CNTs instead of s-CNTs. When CNTs cross from source (S) to drain (D) electrodes, the effective length for the breakdown process depends on CNT orientation.

During a breakdown process, losses occur when the higher voltages required to break long m-CNTs cause the destruction of shorter s-CNTS as well. The invention is a method to reduce losses of s-CNTs by slicing the CNTs so as to inactivate the longer CNTs that degrade the selectivity of the breakdown process. A simple embodiment of the idea is to make a periodic array of open slots over a collection of CNTs and plasma etch the CNT in the slots so as to periodically slice the CNTs. The slot spacing effectively sets a maximum possible CNT length that is active in the device.

In devices having a mixture of s- and m-CNTs, it is possible to break the m-CNTs to obtain devices having only s-SWNTs fully extending between the source and drain electrodes. This is accomplished by backgating the device to turn off the s-CNTs and applying a S-D voltage to drive current through the m-CNTs in order to heat them. At sufficiently high voltages, the temperature of the m-CNTs becomes high enough to oxidize the CNTs in the presence of an oxidizer such as oxygen.

A shortcoming of this electrical breakdown technique is that with large numbers of CNTs in a device, many s-CNTs are also broken as a result of having a distribution of nanotube lengths between S and D electrodes. The electrically generated temperature in a nanotube depends on the current. Longer CNTs require higher breakdown voltages because of a combination of higher resistance as well as heat dissipation to the electrodes and substrate. The higher voltages required to breakdown the longer CNTs will also cause shorter s-CNTs to breakdown as well. Breakdown of all m-CNTs in a device results in high losses of s-CNTs. Methods that produce CNTs on substrates generally lead to a distribution of nanotube orientations which result in a distribution of “effective” lengths between S- and D-electrodes that lead to s-CNT losses during electrically induced breakdown. A device with highly uniform CNT lengths can suffer large s-CNT losses if there is even a single m-CNT with a longer length.

Without slicing, electrical breakdown results in losses over 90 percent of all the CNTs with losses frequently over 99 percent. Using periodic slicing, losses have been reduced to 35 percent which is close to the theoretical fraction of m-SWNTs in a purely random CNT sample. This is especially critical for high power applications where devices will require well in excess of 10,000 CNTs. As the number of CNTs increases, the probability of stray CNTs with long effective lengths becomes very high. The method described here mitigates the problem of having a wide distribution of effective CNT lengths as well as stray long CNTs that would render electrical breakdown ineffective for producing devices having large numbers of purely s-CNTs.

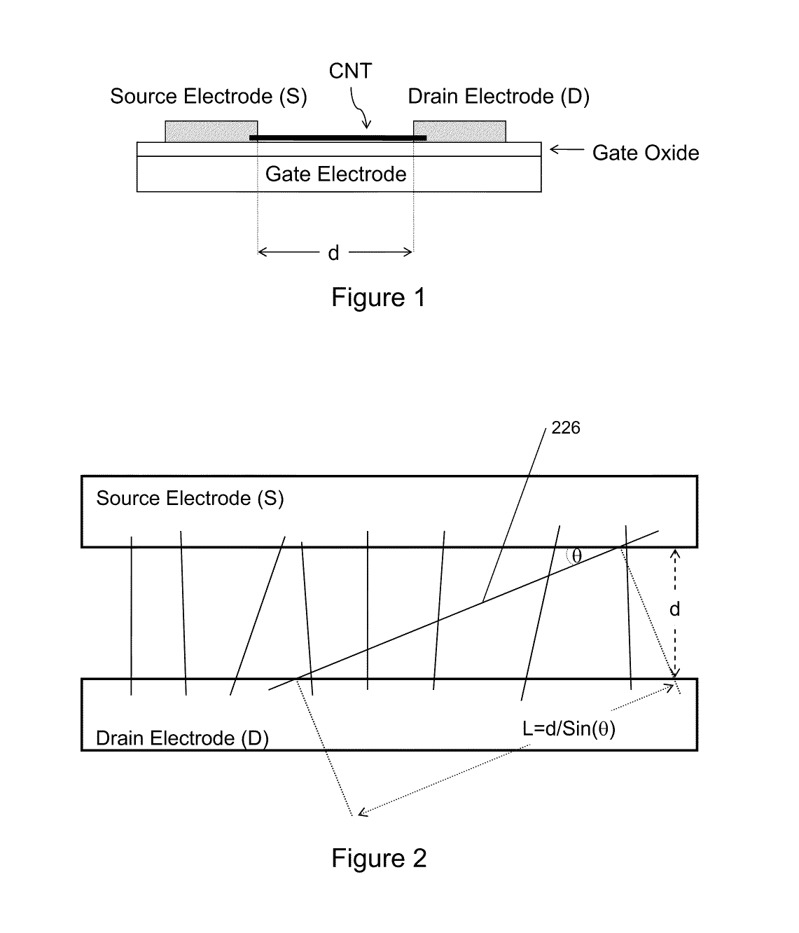

FIG. 1 shows a side view of a structure with a carbon nanotube (CNT) extending between a source electrode (S) and drain electrode (D). Below the carbon nanotube is a gate electrode. A gate electrode is below the gate oxide. With its source, drain, and gate electrodes, this structure is a carbon nanotube transistor. In a specific implementation, the carbon nanotube transistor is a semiconducting carbon nanotube transistor with a semiconducting, single-walled carbon nanotube. More details on carbon nanotube transistors and their manufacture are discussed in U.S. Pat. Nos. 7,301,191 and 7,345,296, which are incorporated by reference.

Typically the gate oxide is relatively thin, such as having a thickness from about 2 to 150 nanometers. The thickness may be thicker than 150 nanometers, such as about 150 to 500 nanometers. There is a distance d between the source and drain electrodes.

FIG. 1 shows a particular orientation to the layers and positioning of the source and drain electrodes. The carbon nanotubes are formed horizontally or parallel to a substrate on which the transistor structure is being fabricated. One of skill in the art would recognize that the orientation and positioning may be changed, while maintaining the same connectivity and functionality.

For example, the source and drain may be swapped. The carbon nanotubes may also be formed vertically with respect to the substrate, such as in a trench, pore, hole, or groove. The gate may be above or beside the carbon nanotube. The electrodes may be stacked with the nanotube oriented substantially normal, as opposed to parallel, to the substrate. Generally the gate runs perpendicular to a length of a nanotube.

FIG. 2 shows a top view of the structure in FIG. 1, where there are numerous carbon nanotubes extending between the source and drain electrodes. The figure shows nine nanotubes, but there can be any number of nanotubes such as 100s or 1000s or more nanotubes. These nanotubes can be used to form a single transistor, where the multiple nanotubes combine in parallel to form a transistor having a greater effective transistor width. Alternatively, if multiple transistors specific transistor widths are desired, a selected number of nanotubes can be separated from the others by breaking (e.g., lithography and etching) the source and drain electrodes so that the desired number of nanotubes connected together.

It is desirable to form the multiple parallel nanotubes adjacent to each other running between the source and drain contacts. However, due to the manufacture, the nanotubes extend between the source and drain electrode at various angles, relative to the source and drain electrodes, and relative to each other. The nanotubes will not necessarily be formed parallel to each other and do not necessarily run perpendicular to the source and drain electrodes. Some nanotubes may cross other nanotubes (such as a nanotube 226), thus shorting these nanotubes together.

To fabricate this structure, the nanotubes may be grown from catalyst strips patterned on a doped silicon wafer substrate having about 400 nanometers of thermal silicon oxide. As shown in FIG. 1, source and drain electrodes are patterned over the nanotube areas and the silicon substrate was used as the gate. In an alternative implementation, the gate is a layer such as polysilicon or metal which is formed on another substrate material. The source and drain electrodes are long rectangular strips that run parallel to each other.

For electrical breakdown, the carbon nanotubes have an effective length L (see FIG. 2) which is determined by the electrode spacing d and the angle the carbon nanotube makes with the electrodes. To simplify the diagram and explain the concepts of the invention more easily, the carbon nanotubes are depicted as being straight. However, in practice, the nanotubes may have bends, curves, ripples, or be curly.

To make a field effect transistors (FETs) with carbon nanotubes, s-CNTs are used. The presence of any m-CNTs will spoil transistor operation. However, typically when growing CNTs on chips, the CNTs are a mixture of m- and s-CNTs, where the fraction of s-CNTs is often close to a theoretical value of about ⅔. This means about 67 percent of the CNTs are s-CNTs and about 33 percent are m-CNTs. After the CNTs are grown (or formed), the m-CNTs are removed, leaving the s-CNTs.

One method to remove m-SWNT is through electrical breakdown in air. Typically, as grown s-CNTs are p-type so that a back gate of positive voltage turns off the s-CNTs. While the s-CNTs are gated off, current is driven through the m-CNTs by applying a bias voltage, V_{sd}, between the source and drain electrodes. The temperature of the m-CNTs will increase with the current. At sufficiently high voltage, V_{bd}, the m-CNT will reach a temperature (e.g., about 600 degrees C.) at which it will oxidize. The particular voltage depends on the nanotube length, L, and the efficiency of thermal dissipation of the substrate, electrodes, and CNTs. For longer L, the CNT resistance increases so that the current decreases for a given applied voltage. Thus, for a given d, longer L requires a higher voltage. The longest CNTs will dictate the voltage used to remove all the m-CNTs from the device.

In principle, if all CNTs would be oriented at θ0=90 degrees (see FIG. 2), or at least at a single angle, there would be a single value for L. However, for most CNT growth or deposition methods, there are a spread of angles resulting in a spread of effective CNT lengths. Also CNTs are typically not perfectly straight as well.

Therefore there will be a range of values for L. A problem is that s-CNTs will breakdown beyond a threshold voltage, so that V_{bd} for long CNTs can destroy s-CNT that have a sufficiently short L. Even systems that produce highly aligned CNTs, such as growth on quartz, have a small fraction of misaligned CNTs. For any given device, it only takes one CNT with a length larger than the average to cause breakdown losses of s-CNTs.

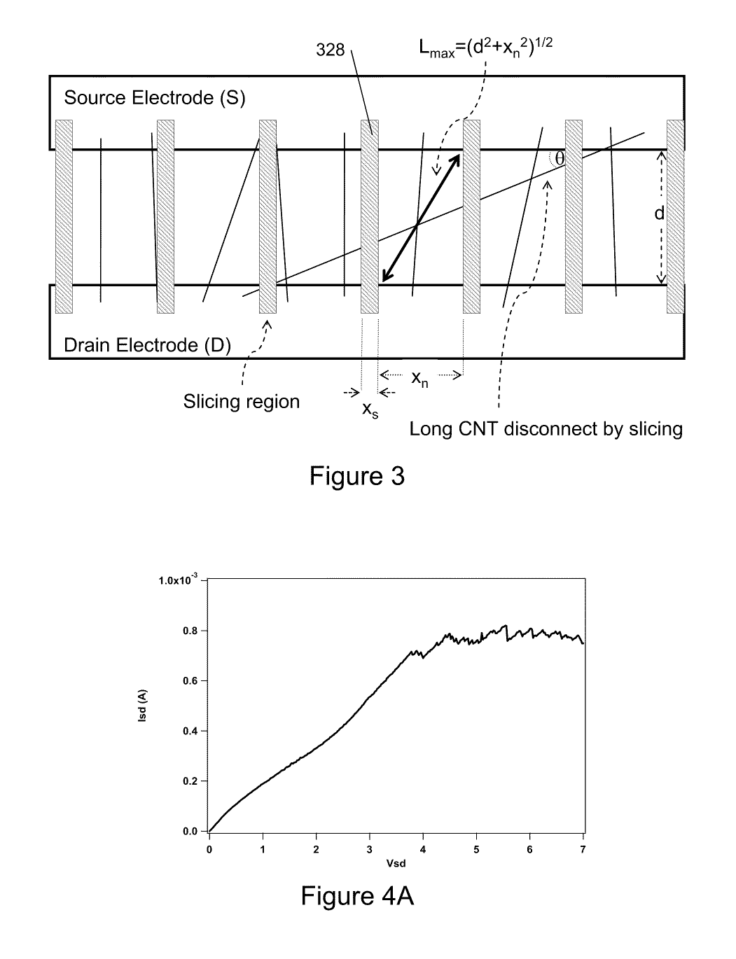

A technique to reduce the range of values for L is to slice, cut, or otherwise break the long nanotubes. FIG. 3 shows a top view of the structure of FIGS. 1 and 2 where slots 328 are formed to slice the long nanotubes. The slots can formed on the structure using lithography. For example, where the slot is on the structure, etching is performed to break the nanotubes. There can be any number of slots arranged in a periodic array.

In an implementation, the slots are open areas having a width Xₛ and separated by resist covered regions Xₙ, (not sliced). Oxygen plasma is used to etch, or slice, the CNTs exposed in the regions Xₛ, leaving the CNTs everywhere else intact. The width Xₙ places a maximum on the effective length, Lₘₐₓ, regardless of the original L.

To quantify the efficiency of the breakdown process, it is useful to approximate the total number of CNTs in a device as inversely proportional to the on-state resistance, Rₒₙ, that is, the resistance when the back gate is sufficiently negative for p-type s-CNTs. This is a simplification because CNTs will have differing intrinsic and contact resistances depending on the band gaps and quality of the contacts. Nevertheless, it is useful to gauge the selectivity by comparing the Rₒₙ before and after breakdown.

The fraction of CNTs remaining after the breakdown process can be gauged by the fraction f_{bd}=Rᵢ/R_{f} where Rᵢ is Rₒₙ before breakdown and R_{f} is Rₒₙ after breakdown. If ⅔ of the CNTs in a device are s-CNTs, then f_{bd} should be about ⅔ after breakdown if only m-CNTs are broken.

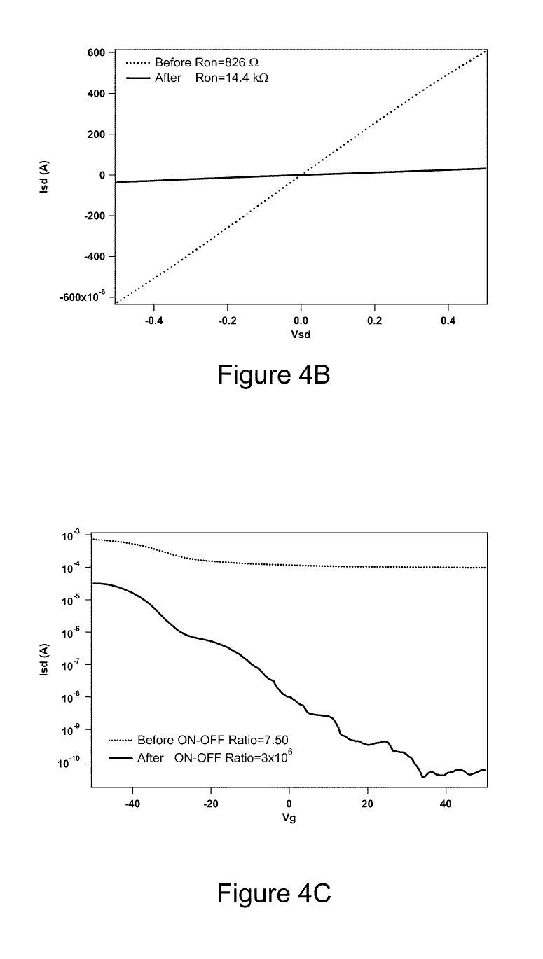

In practice, the breakdown losses are high. FIGS. 4A-4C show a typical breakdown for a device without any periodic slicing. FIG. 4A shows a first breakdown sweep using Vg=+50 volts. Initial breakdown occurs at about 3.5 volts, but breakdown of additional CNTs continues at higher voltages. After the first sweep a low value of the ON-OFF ratio of 91 indicated the presence of m-SWNTs which were completely removed with subsequent sweeps to V_{bd}=9 volts. The before and after I-V curves for I_{sd} vs V_{sd} in the on state (FIG. 4B) give f_{bd}=0.06 with a corresponding ON-OFF ratio of 3×10⁶ (FIG. 4C). For several 500-micron wide and smaller test devices described here, f_{bd}=0.071±0.017, which means that about 90 percent of the s-CNTs were lost in addition to the m-CNTs.

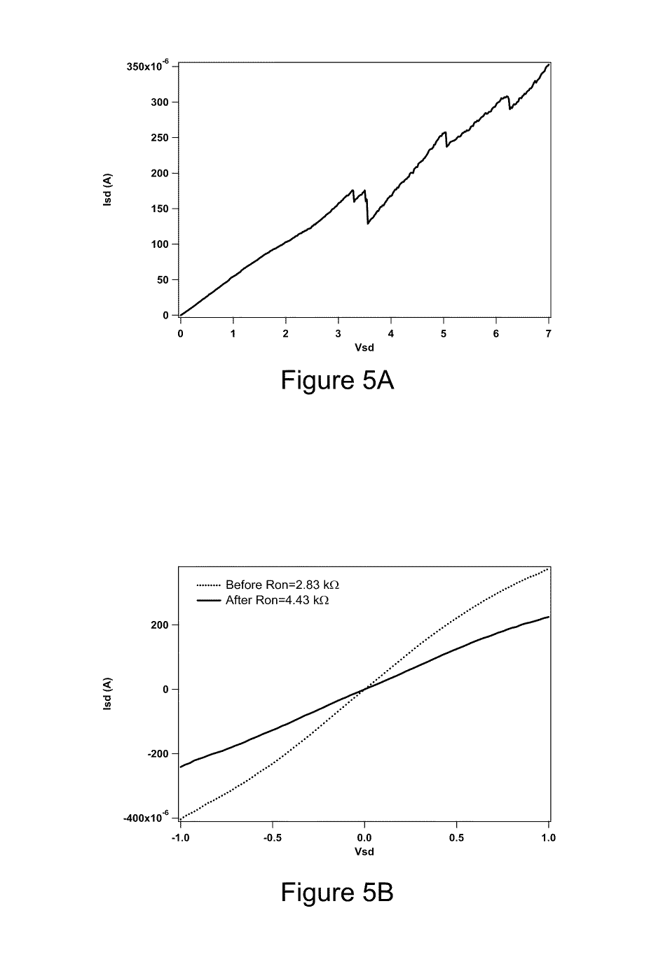

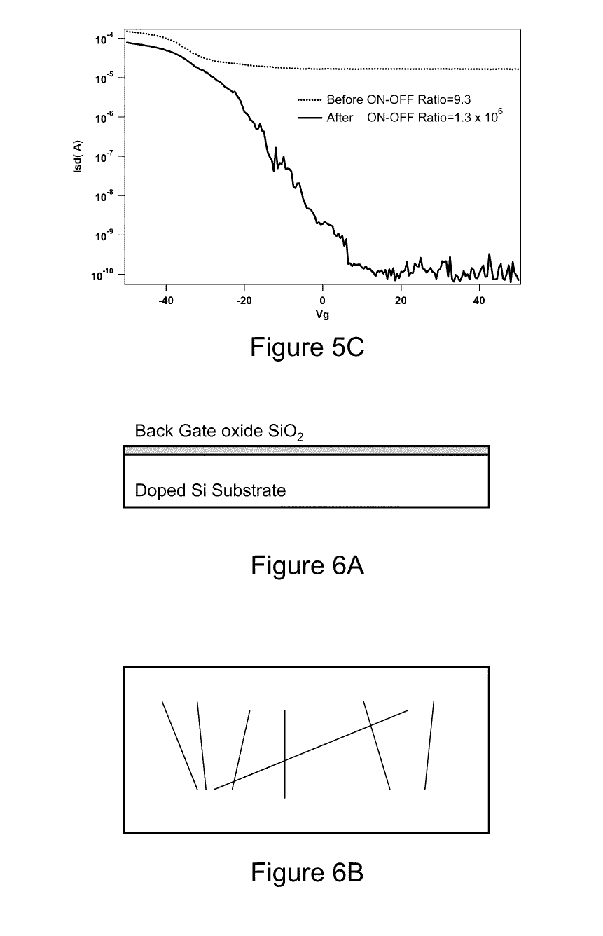

Losses are greatly reduced during breakdown in devices where the CNTs were etched using Xₛ=0.6 μm and Xₙ=0.8 μm. FIGS. 5A-5C show the first breakdown sweep along with before and after I-V curves. As with the device represented by FIGS. 4A-4C, additional breakdown sweeps are used to completely remove the m-CNTs, but the final breakdown voltage was lower, V_{bd}=7 volts. FIG. 5B shows that the loss fraction was only f_{bd}=0.64, suggesting that there was little if no loss of s-CNTs during the breakdown. This trend is consistent over multiple devices on the same chip. Devices without periodic slicing had V_{bd}=9.7±0.6 volts and f_{bd}=0.071±0.017, while those with periodic slicing had V_{bd}=7.2±0.4 volts and f_{bd}=0.32±0.18.

It should be noted that there is an inherent loss for devices with periodically sliced CNTs. For the slot geometry (FIG. 3), this can be quantified by the fraction fₛ=Xₙ/(Xₙ+Xₛ). It is desirable to make the etched slot as narrow as possible to minimize CNTs lost due to the etching. After breakdown, the total loss is then fₜₒₜ=fₛf_{bd}.

By reducing CNT losses due to the breakdown process, the invention will greatly increase the CNT packing density that is achievable in devices requiring only s-CNTs. This will enable the fabrication of CNT-based FETs capable of handling higher current with lower resistance.

Achieving a high-power CNT-based FET requires fabrication of devices having purely s-CNTs. Electrical breakdown is a critical pathway for achieving this goal. The method discussed in this patent facilitates greater selectively when removing m-CNTs by using electrical breakdown.

A specific flow for fabricating nanotube device (including selectively removing m-CNTs) is presented below, but it should be understood that the invention is not limited to the specific flow and steps presented. A flow of the invention may have additional steps (not necessarily described in this patent), different steps which replace some of the steps presented, fewer steps or a subset of the steps presented, or steps in a different order than presented, or any combination of these. Further, the steps in other implementations of the invention may not be exactly the same as the steps presented and may be modified or altered as appropriate for a particular application or based on the equipment used.

A specific flow includes:

1. Deposit CNTs on substrate. CNTs may be deposited by direct growth, spin on, film transfer, or other techniques. The nanotubes may be formed using a catalyst such as palladium, iron, nickel, or cobalt, or combinations of these. Other examples of catalysts include transition metals such as scandium, titanium, vanadium, chromium, manganese, copper, zinc, yttrium, zirconium, niobium, molybdenum, technetium, ruthenium, rhodium, silver, cadmium, hafnium, tantalum, tungsten, rhenium, osmium, iridium, platinum, gold, mercury, rutherfordium, dubnium, seaborgium, bohrium, hassium, meitnerium, ununnilium, unununium, or ununbium, or combinations of these.

FIG. 6A shows a side view of a doped silicon substrate (e.g., less than 0.0005 ohm-centimeter) with a back gate oxide on the substrate. FIG. 6B shows a top view where carbon nanotubes, a mixture of s-CNTs and m-CNTs, have been formed on the surface.

2. Pattern resist for periodic slicing. This can be performed using a masking step and leaving photoresist in areas where slicing is not desirable, and removing photoresist where the CNTs are to be sliced.

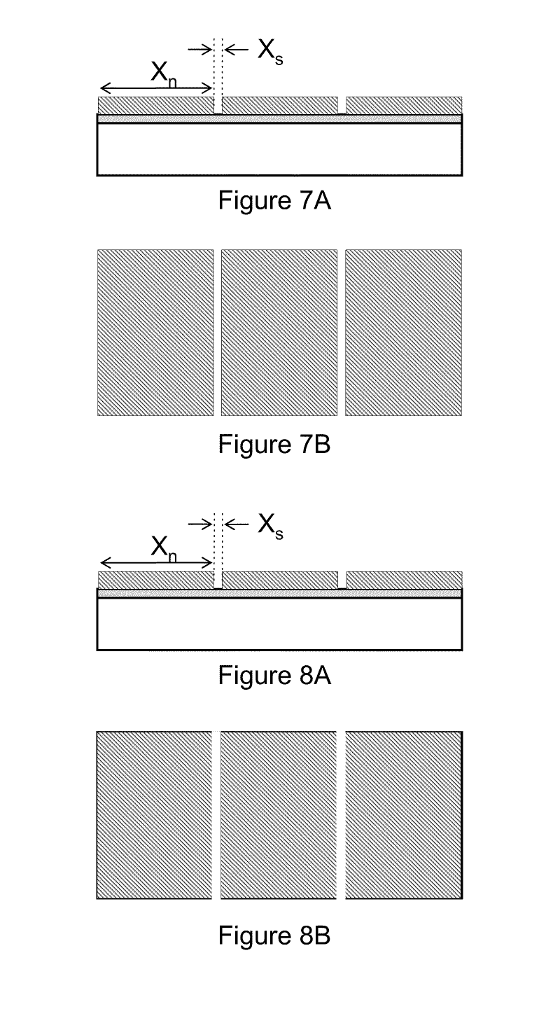

FIG. 7A shows a side view and 7B shows a top view of regions of the substrate covered by photoresist Xₙ and open regions Xₛ, where the photoresist has been removed.

3. Etch CNTs in open areas (e.g., no photoresist) with oxygen plasma. In addition to oxygen plasma etching, other techniques for etching or inactivating CNTs may be used instead. For example, CNTs may be rendered insulating through sidewall functionalization.

FIG. 8A shows a side view and 8B shows top view after etching. The open areas have been etched and any nanotubes in those regions are removed or cut.

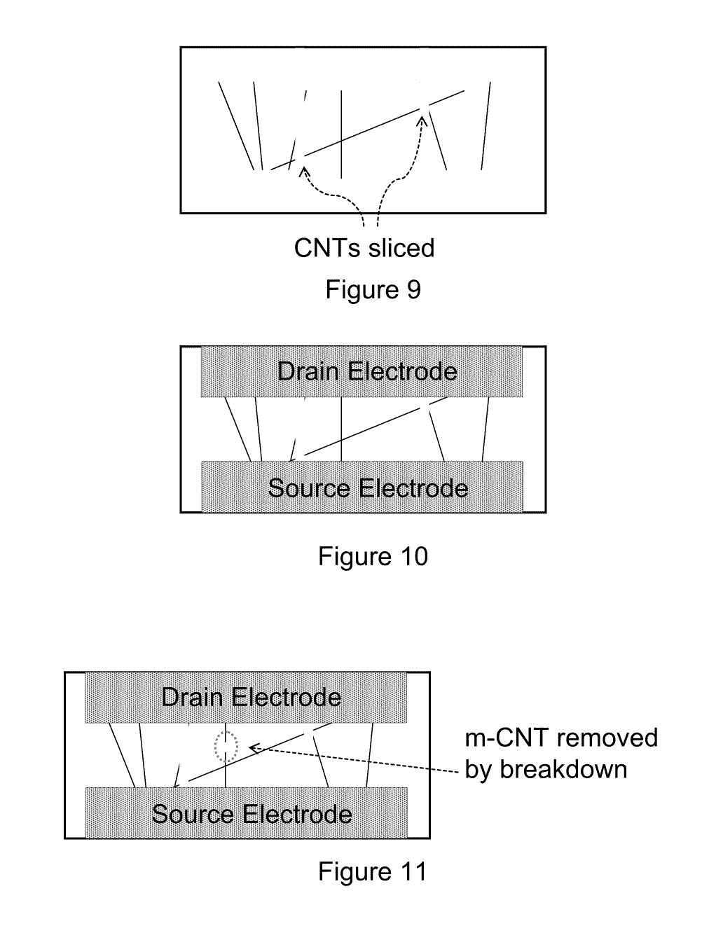

4. Remove resist. FIG. 9 shows that the resist is removed and the sliced CNTs remain.

5. Pattern source and drain electrodes. This is typically performed using a lithography step. FIG. 10 a top view of the structure after the drain and source electrodes are formed.

6. Use breakdown process to break m-CNT. For example, for a device having d=0.8 microns, apply a positive backgate voltage and sweep the source-drain voltage from 0 to 7 volts at 0.25 volts per second. Check for the presence of m-CNTs by measuring the ON-OFF ratio and repeat breakdown sweeps until desired ON-OFF ration is obtained.

FIG. 11 shows a top view of the structure after an electrical breakdown process is used to remove m-CNTs. U.S. provisional patent applications 61/091,041, filed Sep. 19, 2008, and 61/178,411, filed May 14, 2009, and U.S. patent application Ser. No. 12/546,468, filed Aug. 24, 2009, discuss techniques for selective removal for m-CNTs and are incorporated by reference. These techniques may be used in conjunction with the technique described in this patent.

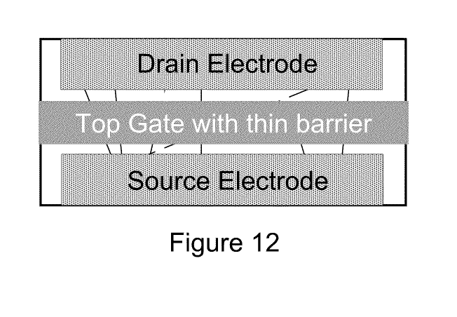

7. If the final device is a transistor, pattern a top gate with thin gate dielectric barrier. Typically, gate oxides for backside gating (FIG. 10) are thick (e.g., 200-400 nanometers). Superior transistor characteristics use a thinner gate. FIG. 12 shows the structure with the top gate with thin barrier (2-20 nanometers).

Using Schottky Barrier

Even with the improved selectivity of the above technique, leakage current can still lead to losses of some s-CNTs. As the CNT density increases, random variations in contact resistance can combine with CNT crossings to cause leakage current to flow through crossed nanotubes, leading to losses in s-CNTs. Therefore, in a further technique, Schottky barriers are used to improve the selectivity of electrical breakdown of carbon nanotubes.

The slotting technique above may be used individually or in combination with this Schottky barrier technique or another technique. And the Schottky barrier technique may be used individually without the above slotting technique, or combined with the slotting or another technique.

Schottky diodes based on carbon nanotubes may be fabricated by using electrical breakdown of the m-CNTs.

For high-power applications, devices will typically have in excess of about 100,000 CNTs with a high density CNTs. Some devices will have 1,000,000 or more CNTs. Losses in s-CNTs during electrical breakdown will limit density of CNTs that can be packed into a device. The present technique reduces undesirable losses in order to achieve higher power devices.

Even though electrical breakdown has be used to remove m-CNTs during fabrication of CNT-based Schottky diodes, the Schottky barrier has not be used in conjunction with electrical breakdown as a means to improve the selectivity of removing m-CNTs. Electrical breakdown can be used to remove all m-CNTs. However, after burn out of m-CTNs, the maximum number of nanotubes observed in the devices was on the order of 4-5, indicating high losses of s-CNTS, which is undesirable for the manufacture of carbon nanotube devices. One reason the advantage of having a Schottky barrier has not been recognized is that the presence of long CNTs in devices has probably led to large losses of s-CNTs. Hence, any benefit of a Schottky barrier to selective electrical breakdown has been obscured by other loss mechanisms.

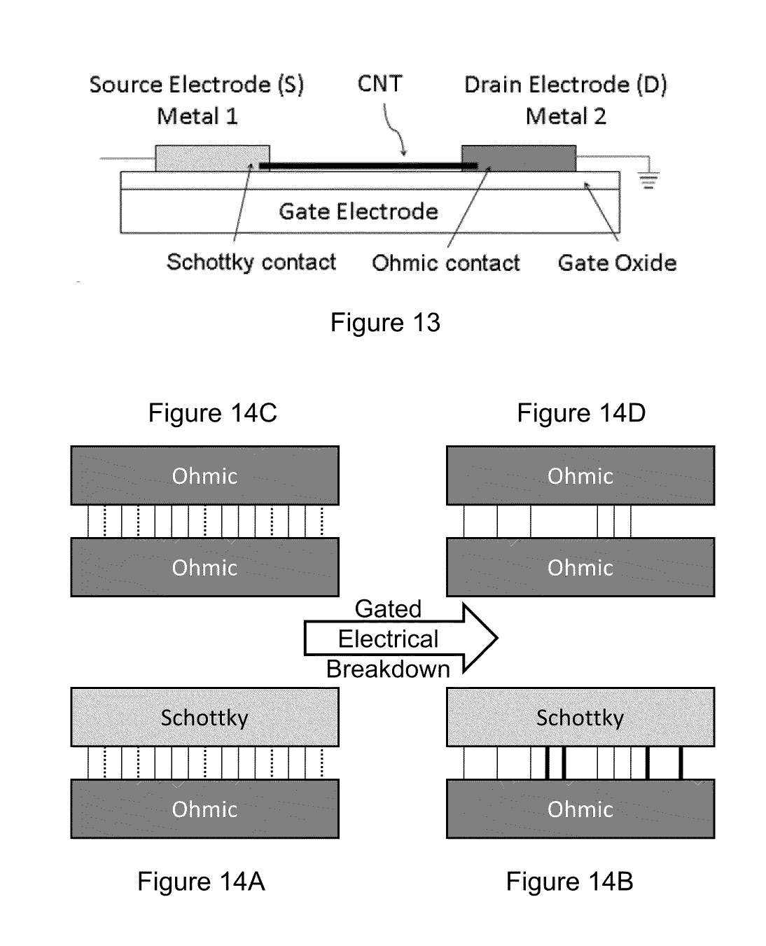

FIG. 13 shows a side view of a structure with a carbon nanotube extending between a source electrode and drain electrode. See description accompanying FIGS. 1 and 2 above for more details. In this structure, there is a Schottky contact between the source and nanotube. There is an ohmic contact between the drain and nanotube.

A technique of the invention takes advantage of Schotty barriers to decrease leakage current through s-CNTs during electrical breakdown removal of m-CNTs. FIGS. 14A and 14B shows a top view of the structure with Schottky and ohmic contacts, while FIGS. 14C and 14D show a similar structure without the Schottky contacts. FIGS. 14A and 14C show the structure and nanotubes before electrical breakdown. FIGS. 14B and 14D show the structure and nanotubes after electrical breakdown. When using the Schottky contacts, the result is s-CNTs removed using the FIG. 14D technique remain (nanotubes show bolded).

A Schottky barrier is formed between metal and semiconductor when they come into contact. For p-type semiconductors, the work function of the metal should be greater than that of the semiconductor. The barrier increases if a negative bias is applied to the semiconductor. This is called “reverse bias” since current flow is suppressed. The barrier decreases with a positive bias and allows current to flow in “forward bias.”

“Ohmic contacts” may have small Schottky barriers. In a given device without doping, the contacts will have a distribution of such barriers. Three types of contacts will be defined for the purposes of this discussion: (1) contacts that have negligible barriers or ohmic contacts (o), (2) contacts with small Schottky barriers (ss), and (3) contacts that have large Schottky barriers (S).

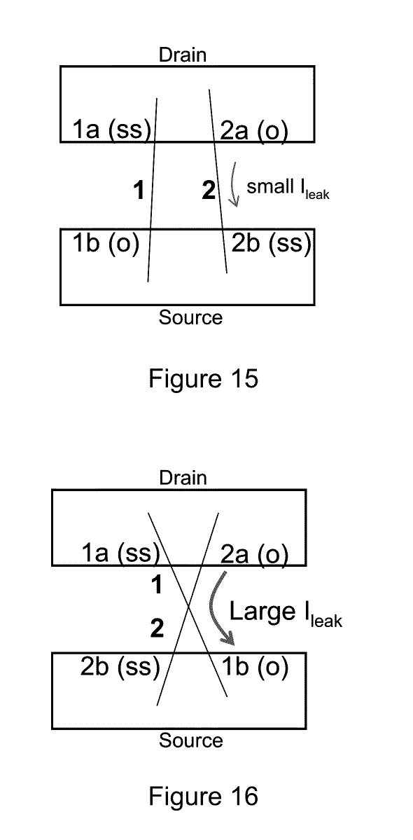

FIG. 15 shows for a first nanotube (labeled 1) a small Schottky barrier contact at the drain (1a) and an ohmic contact at the source (1b). For a second nanotube (labeled 2) an ohmic contact is at the drain (2a) and small Schottky contact at the source (2b). The first and second nanotubes do not cross. For the second nanotube, there is a small leakage current Iₗₑₐₖ between the drain and source when the drain is positively biased. This small leakage can lead to undesirable losses of s-CNTs. At negative bias, the leakage would go in the opposite direction through nanotube 1.

FIG. 16 shows for a first nanotube (labeled 1) a small Schottky barrier contact at the drain (1a) and an ohmic contact at the source (1b). For a second nanotube (labeled 2) an ohmic contact is at the drain (2a) and small Schottky contact at the source (2b). The first and second nanotubes cross and short. There is a large leakage current Iₗₑₐₖ between 2a and 1b, the two ohmic contacts. This large leakage current can lead to undesirable losses of s-CNTs, more than in the FIG. 15 case.

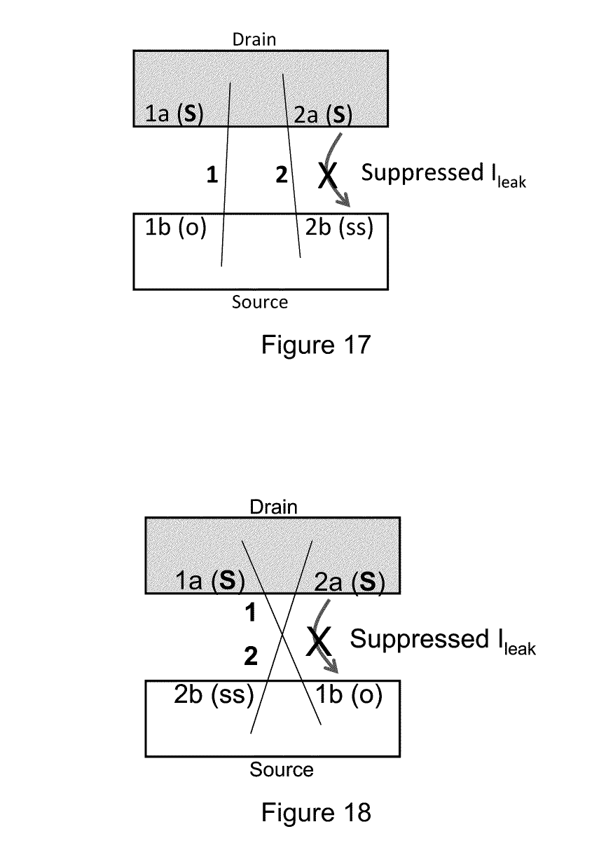

FIG. 17 shows for a first nanotube (labeled 1) a large Schottky barrier contact at the drain (1a) and an ohmic contact at the source (1b). For a second nanotube (labeled 2) a large Schottky contact is at the drain (2a) and small Schottky contact at the source (2b). The first and second nanotubes do not cross. In this configuration, the leakage current Iₗₑₐₖ between 2a and 2b is suppressed. The Schottky contact is engineered to prevent leakage and breakdown of s-CNTs.

FIG. 18 shows for a first nanotube (labeled 1) a large Schottky barrier contact at the drain (1a) and an ohmic contact at the source (1b). For a second nanotube (labeled 2) a large Schottky contact is at the drain (2a) and small Schottky contact at the source (2b). The first and second nanotubes cross and short. In this configuration, the leakage current Iₗₑₐₖ between 2a and 1b is suppressed. The Schottky contact is engineered to prevent leakage and breakdown of s-CNTs.

By designing a large Schottky barrier into one of the contacts, the leakage current can be suppressed, regardless of whether the CNTs are crossing. Examples of metals that can be used to form a Schottky barrier with p-type CNTs are titanium (Ti) and aluminum (Al), while ohmic contacts use palladium (Pd) or platinum (Pt). For n-type CNTs, a Schottky barrier is formed when the metal workfunction is less than that of the CNT, so the metal choice would be reversed.

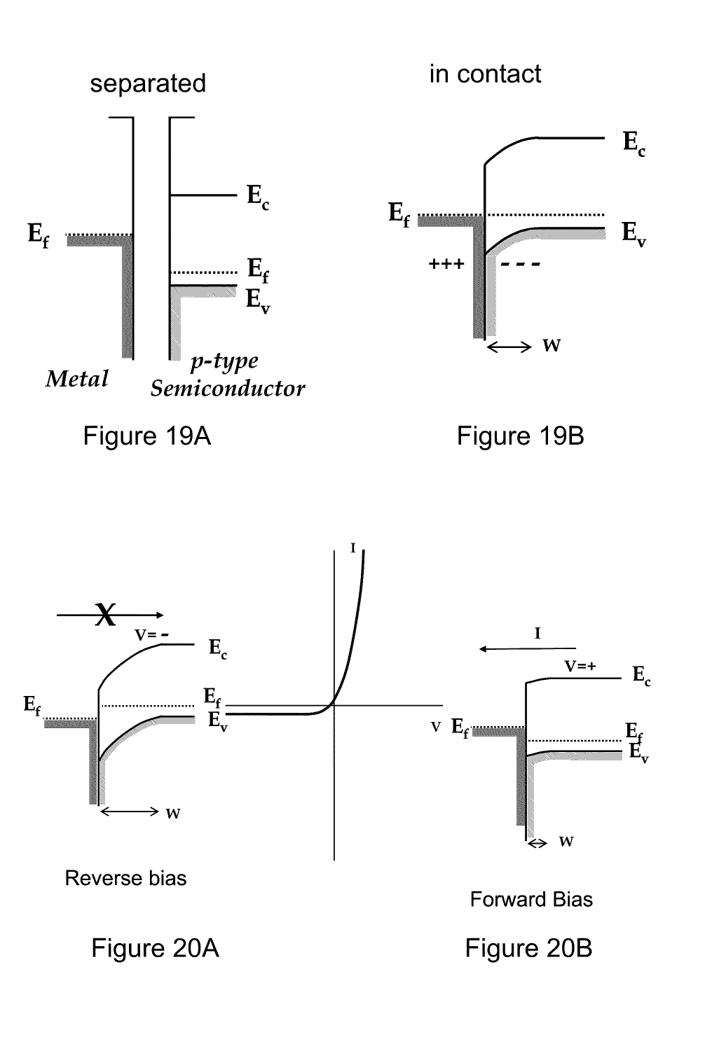

FIGS. 19A-19B show diagrams for a device where the source contact is characterized to be a Schottky contact. In FIG. 19A, the metal and p-type semiconductor are separated. In FIG. 19B, the metal and p-type semiconductor are placed in contact forming the Schottky contact.

FIGS. 20A-20B show the Schottky contact of FIG. 19B when the junction is reverse biased (FIG. 20A) and forward biased (FIG. 20B). If electrical breakdown is done in reverse bias, leakage of the s-CNTs will be suppressed, thus preventing breakdown losses of the s-CNTs.

The effectiveness of using a Schottky barrier to improve breakdown selectivity is useful for devices having a low density of CNTs with minimal CNT crossings. In specific applications of the techniques, two types of devices were tested.

In a first specific implementation of the technique, the device has the structure of FIG. 12 has palladium for both metal 1 and metal 2. For several 500 microns wide and smaller test devices described here, fbd=0.36±0.13, which means that about 50 percent of the s-CNTs were lost in addition to the m-CNTs.

In a second specific implementation, the device has the structure of FIG. 12 where titanium is used for metal 1 and palladium for metal 2. The breakdown selectivity dramatically improved, yielding fbd=0.57±0.13, suggesting s-CNTs losses less than 20 percent. In conjunction with other methods to mitigate the effect of length distribution, introduction of a Schottky barrier should virtually eliminate losses of s-CNTs during electrical breakdown of devices having a high density of CNTs.

By reducing CNT losses due to the breakdown process, the invention will greatly increase the CNT packing density that is achievable in devices requiring only s-CNTs. This will enable the fabrication of CNT based FETs capable of handling higher current with lower resistance.

The above discussion described the invention with respect to p-type semiconducting material, but one skilled in the art will recognize that the invention is also applicable to n-type semiconducting material.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The invention claimed is:

1. A method comprising:
providing a substrate;
forming on a surface of the substrate a mixture of semiconducting and metallic carbon nanotubes;
on the mixture, patterning a first slot and second slot, each having a width W and a spacing S between the first and second slot, wherein W is less than S;
etching the mixture in the slots;
removing the patterning;
forming drain and source electrodes contacting ends of the mixture; and
biasing the drain and source electrode with voltage to remove the metallic carbon nanotubes.

2. A method of claim 1 comprising:
forming a Schottky barrier between an end of the mixture and the source electrode.

3. The method of claim 1 wherein the forming drain and source electrodes occurs before patterning a first slot and a second slot.

4. The method of claim 1 wherein the forming drain and source electrodes occurs after patterning a first slot and a second slot.

5. The method of claim 1 wherein the etching the mixture in the slots is replaced by inactivating the mixture in the slots.

6. A method comprising:
providing a silicon substrate;
forming on a surface of the substrate a mixture of semiconducting and metallic carbon nanotubes;
forming drain and source electrodes contacting ends of the mixture, wherein between a first end of the mixture and the source electrode is a Schottky barrier contact; and
biasing the drain and source electrode with voltage to remove the metallic carbon nanotubes.

7. The method of claim 6 wherein before forming the Schottky barrier, the method comprises:
on the mixture, patterning a first slot and second slot, each having a width W and a spacing S between the first and second slot, wherein W is less than S;
etching the mixture in the slots; and
removing the patterning.

8. The method of claim 6 wherein between a second end of the mixture and the drain electrode is an ohmic contact.

9. A method comprising:
providing a substrate;
forming on a surface of the substrate a mixture of semiconducting and metallic carbon nanotubes;
forming a source electrode comprising a Schottky barrier contact that couples to first ends of the mixture;
forming a drain electrode that electrically couples to second ends of the mixture; and
biasing the drain and source electrode with a voltage to remove the metallic carbon nanotubes.

10. The method of claim 9 wherein before forming the Schottky barrier, the method comprises:
on the mixture, patterning a first slot and second slot, each having a width W and a spacing S between the first and second slot, wherein W is less than S;
etching the mixture in the slots; and
removing the slot patterning.

11. The method of claim 9 wherein a first carbon nanotube of the mixture crosses and couples to at least a second carbon nanotube and a third carbon nanotube.

12. The method of claim 11 comprising:
on the mixture, patterning a first slot and second slot, each having a width W and a spacing S between the first and second slot, wherein W is less than S; and
etching the mixture in the slots, wherein the first carbon nanotube is sliced below the first slot and the second slot, thereby breaking the first carbon nanotubes into at least three portions.

13. The method of claim 9 wherein the source electrode comprises a rectangular structure having a width SW and length SL, the drain electrode comprises a rectangular structure having a width DW and length DL, SL is greater than SW, DL is greater than DW, and the source is separated from the drain a space having a width D.

14. The method of claim 13 wherein a first carbon nanotube of the mixture extends from the first electrode to the second electrode and has a length L1 greater than D, and a second carbon nanotube of the mixture extends from the first electrode to the second electrode and has a length L2 greater than L1, wherein an angle A1 between the first carbon nanotube and the first electrode is different from an angle A2 between the second carbon nanotube and the first electrode.

15. The method of claim 13 wherein before forming the mixture, forming on the substrate a thermal gate oxide comprising a thickness from about 2 nanometers to about 500 nanometers.

16. The method of claim 9 wherein the source electrode and drain electrode comprise at least one of metal, aluminum, copper, titanium, or tungsten.

17. The method of claim 9 comprising:
before forming the mixture, depositing a catalyst on the substrate comprising at least one of palladium, iron, nickel, or cobalt.

18. The method of claim 9 wherein as a result of the biasing, greater numbers of metallic carbon nanotubes are removed from the mixture than semiconducting carbon nanotubes.

19. The method of claim 9 wherein as a result of the biasing, at least twice as many metallic carbon nanotubes are removed than semiconducting carbon nanotubes.

20. The method of claim 9 wherein as a result of the biasing, at least ten times more metallic carbon nanotubes are removed than semiconducting carbon nanotubes.
